(19) United States
(12) Patent Application Publication
(10) Pub. No.: US 2025/0285957 A1
(43) Pub. Date: Sep. 11, 2025

(54) INTERPOSER SUBSTRATE AND SEMICONDUCTOR PACKAGE INCLUDING THE SAME

(71) Applicant: SAMSUNG ELECTRO-MECHANICS CO., LTD., Suwon-si (KR)

(72) Inventors: Chi Hyeon Jeong, Suwon-si (KR); Hyunsang Kwak, Suwon-si (KR); Seok Hwan Kim, Suwon-si (KR); Chulmun Kang, Suwon-si (KR)

(73) Assignee: SAMSUNG ELECTRO-MECHANICS CO., LTD., Suwon-si (KR)

(21) Appl. No.: 18/981,023

(22) Filed: Dec. 13, 2024

(30) Foreign Application Priority Data
Mar. 7, 2024 (KR) 10-2024-0032514

(51) Int. Cl. H01L 23/498; H01L 23/15; H01L 23/367; H01L 23/552

(52) U.S. Cl. CPC H01L 23/49833; H01L 23/3675; H01L 23/49816; H01L 23/552; H01L 23/15

(57) ABSTRACT

An interposer substrate includes: a core portion that includes a first surface and a second surface opposing each other, includes a via penetrating from the first surface to the second surface, and includes glass; and a conductive member that is disposed in only a portion of the via. The via includes: a first portion penetrating a portion of the core portion from the first surface and a second portion penetrating another portion of the core portion to be connected to the first portion from the second surface and at which the conductive member is disposed.

### CROSS-REFERENCE TO RELATED APPLICATION

This application claims priority to and the benefit of Korean Patent Application No. 10-2024-0032514 filed at the Korean Intellectual Property Office on Mar. 7, 2024, the entire contents of which are incorporated herein by reference.

### TECHNICAL FIELD

The present disclosure relates to an interposer substrate and a semiconductor package.

### BACKGROUND

As an electronic component is required to be highly functionalized, light, thin, short, and small, a circuit substrate (or a circuit board) installed inside the electronic component is also required to be highly functionalized, light, thin, short, and small. For this purpose, a circuit pattern of the circuit substrate is finely designed, and semiconductor elements that perform various functions are disposed inside to realize the high functionality.

A plurality of printed circuit boards at which chips are respectively disposed may be vertically stacked to form a semiconductor package such as a stacked package, a package on package (POP), or the like. A stacked package is a stacked structure that maintains a certain interval between the upper and lower packages due to a thickness of the chip, and a structure such as a metal post may be used to maintain the certain interval.

On the other hand, an interposer market is growing due to a high specification of a set and adoption of a high bandwidth memory (HBM). Currently, an organic material is mainstream of an interposer material according to a traditional substrate manufacturing method, but a method of using a glass material as the interposer material is being developed.

A small and dense via has to be formed in a high-speed HBM. The glass substrate is known to have a better warpage characteristic and better flatness, have relatively fewer problems during internal processing, and be advantageous in reducing Line and Space (L/S) compared with the substrate using the organic material. Accordingly, it is necessary to develop the interposer substrate using glass.

### SUMMARY

One aspect of the present disclosure is to provide an interposer substrate and a semiconductor package capable of reducing occurrence of a warpage defect, increasing thermal stability and signal count, lowering a height of the semiconductor package, and improving a heat dissipation characteristic.

However, problems to be solved by embodiments of the present disclosure are not limited to the above-described problem and may be variously extended in a range of technical ideas included in the present disclosure.

An interposer substrate according to an embodiment includes: a core portion that includes a first surface and a second surface opposing each other, includes a via penetrating from the first surface to the second surface, and includes glass; and a conductive member that is disposed in only a portion of the via. The via includes: a first portion penetrating a portion of the core portion from the first surface; and a second portion penetrating another portion of the core portion to be connected to the first portion from the second surface and at which the conductive member is disposed.

The core portion may include a cavity on the second surface, and the via may be provided in a plural number around the cavity.

The plurality of vias may be disposed along a circumference of the cavity.

The interposer substrate may further include a heat dissipating portion penetrating and extending from the first surface to the cavity.

The heat dissipating portion may be provided in a plural number, and the plurality of heat dissipating portions may be disposed to be spaced apart from each other.

The first surface and the second surface may oppose each other in a first direction, and the heat dissipating portion may have a plate shape extending in a direction perpendicular to the first direction.

The interposer substrate may further include a protection portion shielding electromagnetic interference by covering a side surface of the cavity.

In the first portion or the second portion, a width of one outer end of the core portion may be greater than a width of the other inner end of the core portion.

The first portion and the second portion may have a symmetrical shape.

Among the first portion and the second portion, the conductive member may be disposed only in the second portion.

An interposer substrate according to another embodiment includes: a core portion that includes a first surface and a second surface opposing each other, includes a via penetrating from the first surface to the second surface, includes a cavity on the second surface, and includes glass; a conductive member that is disposed in a portion of the via; and a heat dissipating portion that penetrates and extends from the first surface to the cavity. The via includes: a first portion penetrating a portion of the core portion from the first surface; and a second portion penetrating another portion of the core portion to be connected to the first portion from the second surface and at which the conductive member is disposed.

The via may be provided in a plural number around the cavity.

The plurality of vias may be disposed along a circumference of the cavity.

The heat dissipating portion may be provided in a plural number, and the plurality of heat dissipating portions may be disposed to be spaced apart from each other.

The first surface and the second surface may oppose each other in a first direction, and the heat dissipating portion may extend in a direction perpendicular to the first direction.

In the first portion or the second portion, a width of one outer end of the core portion may be greater than a width of the other inner end of the core portion.

The first portion and the second portion may have a symmetrical shape.

A semiconductor package according to an embodiment includes: an interposer substrate; an upper package that is disposed at one side of the interposer substrate and includes a first circuit substrate including an insulating layer and a circuit layer, and a connection member that is disposed above one surface of the interposer substrate to connect the upper package and the interposer substrate. The interposer substrate includes a core portion that includes a first surface and a second surface opposing each other, includes a via penetrating from the first surface to the second surface, and includes glass and a conductive member that is filled in a portion of the via, and the via includes a first portion penetrating a portion of the core portion from the first surface and providing a space in which the connection member is disposed and a second portion penetrating another portion of the core portion to be connected to the first portion from the second surface and at which the conductive member is disposed.

The semiconductor package may further include a lower package disposed on the other side of the interposer substrate and including a second circuit substrate including an insulating layer and a circuit layer.

The core portion may have a cavity on the second surface, and the semiconductor package may further include a heat dissipating portion penetrating and extending from the first surface to the cavity.

According to the interposer substrate and the semiconductor package according to the embodiment, occurrence of a warpage defect may be reduced, thermal stability and signal count may be increased, a power transfer characteristic may be improved, a height of an entire semiconductor package may be lowered, and a heat generated from an electronic element may be efficiently transferred and dispersed to the outside of the interposer substrate.

### BRIEF DESCRIPTION OF THE DRAWINGS

FIG. 1 is a cross-sectional view of a semiconductor package according to an embodiment.

FIG. 2 is a cross-sectional view showing a portion of the semiconductor package according to an embodiment.

FIG. 3 is a perspective view of an interposer substrate according to an embodiment.

FIG. 4 is a cross-sectional view showing a portion of a semiconductor package according to another embodiment.

FIG. 5 is a perspective view of an interposer substrate according to another embodiment.

FIG. 6 is a cross-sectional view showing a portion of a semiconductor package according to another embodiment.

FIG. 7 is a perspective view of an interposer substrate according to another embodiment.

FIG. 8 is a cross-sectional view showing a portion of a semiconductor package according to another embodiment.

FIG. 9 is a cross-sectional view of a semiconductor package according to another embodiment.

FIGS. 10 to 15 are cross-sectional views showing a method for manufacturing the semiconductor package according to an embodiment.

FIGS. 16 to 20 are cross-sectional views showing a method for manufacturing the semiconductor package according to another embodiment.

### DETAILED DESCRIPTION OF THE EMBODIMENTS

Embodiments of the present disclosure will be described more fully hereinafter with reference to the accompanying drawings so that those skilled in the art easily implement the embodiments. In order to clearly describe the present disclosure, parts or portions that are irrelevant to the description are omitted, and identical or similar constituent elements throughout the specification are denoted by the same reference numerals. In the accompanying drawings, some elements are enlarged, omitted, or schematically shown, and a size of each element does not accurately reflect its real size.

The accompanying drawings are only for easy understanding of the embodiment disclosed in the present specification, and the technical idea disclosed in this specification is not limited by the accompanying drawings, and the present disclosure should be understood to include all changes, equivalents, and substitutes included in the spirit and technical range of the present disclosure.

Terms including an ordinal number such as first, second, and the like may be used to describe various elements, but the elements are not limited by the terms. The terms are used only for a purpose of distinguishing one element from another element.

It will be understood that when an element such as a layer, film, region, or substrate is referred to as being “on” or “above” another element, it may be directly on another element or an intervening element may also be present. In contrast, when an element is referred to as being “directly on” another element, there is no intervening element present. Further, throughout the specification, the word “on” or “above” a target element will be understood to be disposed above or below the target element, and will not necessarily be understood to be disposed “at an upper side” based on a direction opposite to a gravitational direction

Throughout the specification, terms such as “comprise” or “have” are intended to designate that a feature, number, step, operation, constituent element, part, or combination thereof described in the specification exists, and it should be understood as not precluding the possibility of the presence or addition of one or more other features, numbers, steps, actions, constituent elements, parts, or combinations thereof. Thus, unless explicitly described to the contrary, the word “comprise” and variations such as “comprises” or “comprising” will be understood to imply the inclusion of stated elements but not the exclusion of any other elements.

Further, throughout the specification, the phrase “on a plane” means viewing a target portion from the top, and the phrase “on a cross-section” means viewing a cross-section formed by perpendicularly cutting a target portion from the side.

Throughout the specification, when it is described that a part is “coupled” to another part, the part may be “directly or physically connected” to the other part or “indirectly or non-contact coupled” to the other part with a third part therebetween.

Throughout the specification, “connected” does not mean only when two or more elements are directly connected, but also when two or more elements are indirectly connected through another element, or when physically connected or electrically connected, and it may include a case in which substantially integral parts are connected to each other although they are referred to by different names according to positions or functions.

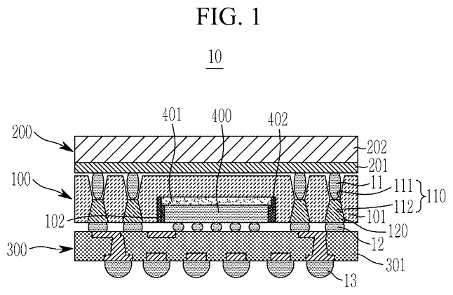

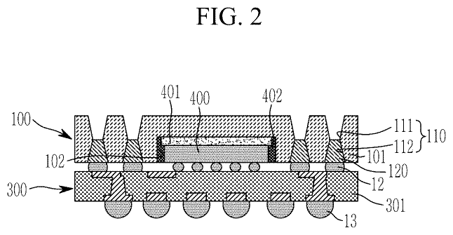

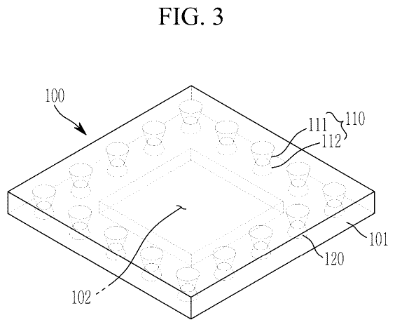

FIG. 1 is a cross-sectional view of a semiconductor package according to an embodiment, FIG. 2 is a cross-sectional view showing a portion of the semiconductor package according to an embodiment, and FIG. 3 is a perspective view of an interposer substrate according to an embodiment.

Referring to FIGS. 1 to 3, the semiconductor package 10 according to the embodiment may include the interposer substrate 100, an upper package 200 disposed at one side of the interposer substrate 100, a lower package 300 disposed at the other side of the interposer substrate 100, a first electronic element 400 connected to the lower package 300 and disposed within a cavity 102 of the interposer substrate 100, a first connection member 11 disposed partially in the interposer substrate 100 to connect the interposer substrate 100 and the upper package 200, a second connection member 12 connecting the interposer substrate 100 and the lower package 300, and a third connection member 13 connecting the lower package 300 to the outside.

The interposer substrate 100 according to the embodiment may include a core portion 101 having at least one via 110 penetrating the interposer substrate 100, and a conductive member 120 filled in a portion of the via 110. One surface of the core portion 101 may have the cavity 102.

The upper package 200 may include a first circuit substrate (or a first circuit board) 201 and a second electronic element 202 mounted on the first circuit substrate 201. Although not shown in FIG. 1, the first circuit substrate 201 may include an insulating layer, a conductive layer, and a via layer. The insulating layer of the first circuit substrate 201 may be formed of at least one resin selected from an epoxy resin, a polyimide (PI) resin, a BT resin, a liquid crystal polymer (LCP), and the like, and specifically, may include a prepreg (PPG), an ABF film, or the like. Additionally, the insulating layer of the first circuit substrate 201 may include a glass fiber, a filler, or the like. On the other hand, although not shown in FIG. 1, the insulating layer of the first circuit substrate 201 may be formed of a plurality of layers, and the number of layers is not limited.

A conductive layer constituting a circuit may be disposed on or in the insulating layer of the first circuit substrate 201. The conductive layer of the first circuit substrate 201 may provide a path for transferring an electric signal, and may be formed of at least one of copper (Cu), silver (Ag), palladium (Pd), aluminum (Al), nickel (Ni), titanium (Ti), gold (Au), and platinum (Pt).

As an example, the first circuit substrate 201 may not include a cavity. In this case, the second electronic element 202 may be mounted on an upper surface of the first circuit substrate 201. For example, the second electronic element 202 may be mounted on the first circuit substrate 201 using a wire bonding method, a flip chip mounting method, or the like

The second electronic element 202 may be at least one of an active element, a passive element, and an integrated circuit. The upper package 200 may be connected to the interposer substrate 100 through the first connection member 11. The first connection member 11 may be a solder ball or the like.

The lower package 300 may include a second circuit substrate (or a second circuit board) 301. The second circuit substrate 301 may include an insulating layer, a conductive layer, and a via layer. The insulating layer of the second circuit substrate 301 may be formed of at least one resin selected from an epoxy resin, a polyimide (PI) resin, a BT resin, a liquid crystal polymer (LCP), and the like, and specifically, may include a prepreg (PPG), an ABF film, or the like. Additionally, the insulating layer of the second circuit substrate 301 may include a glass fiber, a filler, or the like. On the other hand, although not shown in FIG. 1, the insulating layer of the second circuit substrate 301 may be formed of a plurality of layers, and the number of layers is not limited.

A conductive layer constituting a circuit therein may be disposed in or on the insulating layer of the second circuit substrate 301. The conductive layer of the second circuit substrate 301 may provide a path for transferring an electric signal, and may be formed of at least one of copper (Cu), silver (Ag), palladium (Pd), aluminum (Al), nickel (Ni), titanium (Ti), gold (Au), and platinum (Pt).

The lower package 300 may be connected to the interposer substrate 100 through the second connection member 12. The lower package 300 may be connected to the first electronic element 400 through the second connection member 12. The second connection member 12 may be a solder ball or the like. The first electronic element 400 may be at least one of an active element, a passive element, and an integrated circuit.

If necessary, a conductive film 401 may be disposed between the first electronic element 400 and the core portion 101. The conductive film 401 may bond the first electronic element 400 to the core portion 101. A molding material 402 may be disposed in a space of the cavity 102 where the first electronic element 400 is not disposed. The molding material 402 may fix the first electronic element 400.

Hereinafter, the interposer substrate 100 will be described in detail with reference to FIG. 2 and FIG. 3.

Referring to FIG. 2 and FIG. 3, the core portion 101 may be a glass substrate. The core portion 101 may have a first surface and a second surface that oppose each other in a first direction. As an example, the upper package 200 may be disposed above an upper portion of the interposer substrate 100 along the first direction. The lower package 300 may be disposed below a lower portion of the interposer substrate 100 along the first direction. The first surface may be one surface facing the upper package 200 of the semiconductor package 10.

The via 110 may penetrate from the first surface to the second surface of the core portion 101. The via 110 may be provided in a plural number. The cavity 102 may be disposed on the second surface of the core portion 101. The cavity 102 may have a shape that is depressed in the first direction from the second surface. The via 110 may be disposed at one side of the cavity 102. As an example, the plurality of vias 110 may be disposed along a circumference of the cavity 102 at a periphery of the cavity 102. The plurality of vias 110 may be disposed along one edge region of the cavity 102. The via 110 may include a first portion 111 penetrating a portion of the core portion 101 from the first surface, and a second portion 112 penetrating the remaining portion of the core portion 101 to be connected to the first portion 111 from the second surface.

The first portion 111 may have an opening on the first surface. In the first portion 111, a width of one outer end of the core portion 101 along the first direction may be greater than a width of the other inner end of the core portion 101. The first portion 111 may have a shape in which a width of the first portion 111 along a direction perpendicular to the first direction increases as it goes toward the outside of the core portion 101. The first portion 111 may have a shape in which a width of the first portion 111 increases as it approaches the first surface along the first direction.

The second portion 112 may have an opening on the second surface. In the second portion 112, a width of one outer end of the core portion 101 along the first direction may be greater than a width of the other inner end of the core portion 101. The second portion 112 may have a shape in which a width of the second portion 112 along a direction perpendicular to the first direction increases as it goes toward the outside of the core portion 101. The second portion 112 may have a shape in which a width of the second portion 112 increases as it approaches the second surface along the first direction.

The first portion 111 and the second portion 112 may form a symmetrical shape with respect to a reference surface perpendicular to the first direction. However, the present disclosure is not limited thereto, and heights (or thicknesses) of the first portion 111 and the second portion 112 may be different.

A portion of the via 110 may be filled with the conductive member 120. At least a portion of the second portion 112 may be filled with the conductive member 120. The conductive member 120 may be disposed at the second portion 112. Accordingly, the first portion 111 may form an interior wall, the conductive member 120 may form a bottom surface, and a groove portion having an opening may be formed on the first surface. In FIG. 2 and FIG. 3, the conductive member 120 is shown to be filled in an entire second portion 112, but the present disclosure is not limited thereto, and the conductive member 120 may be disposed to be filled in only a portion of the second portion 112. Additionally, it is possible for the conductive member 120 to be additionally filled in a portion of the first portion 111. As an example, the conductive member 120 may include copper (Cu).

The inside of the first portion 111 may provide a space in which the first connection member 11 is disposed. The first connection member 11 may be disposed inside the first portion 111. In other words, at least a portion of the first connection member 11 may be accommodated in a groove space of the core portion 101 formed by the first portion 111 of the via 110. The first connection member 11 may be disposed to be connected to the conductive member 120. The first connection member 11 may be disposed inside the first portion 111 so as to contact the conductive member 120. The first connection member 11 may be disposed to be in contact with one surface of the conductive member 120 exposed upwardly in the first direction. The first connection member 11 may connect the upper package 200 and the interposer substrate 100.

The second connection member 12 may be disposed to be connected to the conductive member 120. The second connection member 12 may be disposed to be in contact with the other surface of the conductive member 120 exposed to a lower side thereof in the first direction. The second connection member 12 may connect the lower package 300 and the interposer substrate 100.

According to the interposer substrate and semiconductor package according to the above-mentioned embodiment, occurrence of a warpage defect may be reduced because a glass core is disposed between the upper package and the lower package, thermal stability and signal count may be increased because a via is disposed at the glass core, and a power transfer characteristic may be improved. Additionally, because the connection member is disposed inside the via, a height of the entire semiconductor package may be lowered.

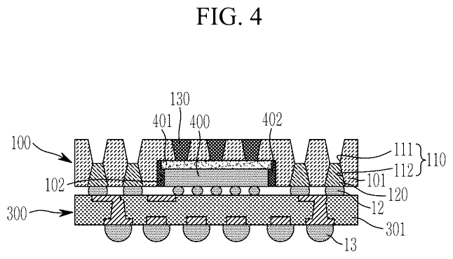

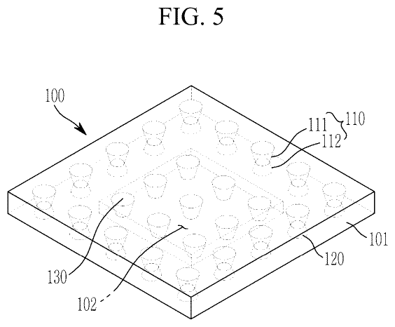

Hereinafter, an interposer substrate 100 and a semiconductor package 10 according to another embodiment will be described with reference to FIG. 4 and FIG. 5.

FIG. 4 is a cross-sectional view showing a portion of the semiconductor package according to the other embodiment, and FIG. 5 is a perspective view of the interposer substrate according to the other embodiment.

Referring to FIG. 4 and FIG. 5, the interposer substrate 100 according to the present embodiment is similar to the interposer substrate 100 according to the embodiment described with reference to FIG. 2 and FIG. 3. A detailed description of the same component is omitted.

Referring to FIG. 4 and FIG. 5, the interposer substrate 100 according to the present embodiment may further include a heat dissipating portion 130 connected to a cavity 102 compared with the interposer substrate 100 according to the embodiment shown in FIG. 2 and FIG. 3. The heat dissipating portion 130 may penetrate and extend form a first surface of a core portion 101 to the cavity 102. The heat dissipating portion 130 may contact a first electronic element 400 (if necessary, a conductive film 401 if the conductive film 401 is disposed between the first electronic element 400 and the core portion 101) disposed in the cavity 102.

The heat dissipating portion 130 may be provided in a plural number. The heat dissipating portion 130 may be disposed at one side of the cavity 102 along a first direction. As an example, a plurality of heat dissipating portions 130 may be disposed at a region of the core portion 101 corresponding to the cavity 102. The plurality of heat dissipating portions 130 may include portions disposed to be arranged in one direction. The plurality of heat dissipating portions 130 may be disposed to be spaced apart from each other.

The heat dissipating portion 200 may include at least one of copper (Cu), aluminum (Al), silver (Ag), tin (Sn), gold (Au), nickel (Ni), lead (Pb), titanium (Ti), and an alloy thereof.

According to the interposer substrate and the semiconductor package according to the other embodiment described above, a heat generated from the electronic element disposed in the cavity may be efficiently transferred and dispersed to the outside of the interposer substrate through the heat dissipating portion.

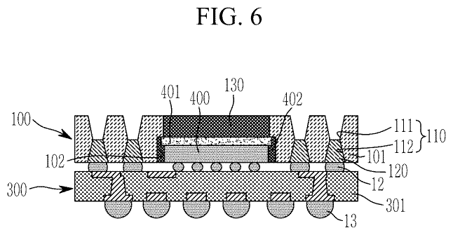

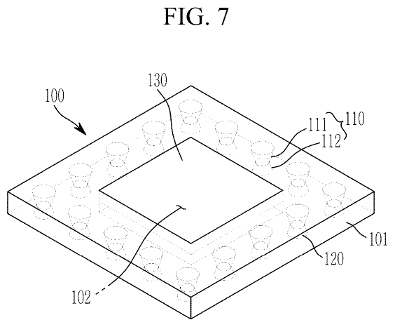

Hereinafter, an interposer substrate 100 and a semiconductor package 10 according to another embodiment will be described with reference to FIG. 6 and FIG. 7.

FIG. 6 is a cross-sectional view showing a portion of the semiconductor package according to the other embodiment, and FIG. 7 is a perspective view of the interposer substrate according to the other embodiment.

Referring to FIG. 6 and FIG. 7, the interposer substrate 100 according to the present embodiment is similar to the interposer substrate 100 according to the other embodiment described with reference to FIG. 4 and FIG. 5. A detailed description of the same component is omitted.

Referring to FIG. 6 and FIG. 7, the interposer substrate 100 according to the present embodiment may have a heat dissipating portion 130 with a large planar area compared with the interposer substrate 100 according to the other embodiment shown in FIG. 4 and FIG. 5. The heat dissipating portion 130 may be disposed to penetrate from a first surface of a core portion 101 to a cavity 102. The heat dissipating portion 130 may contact a first electronic element 400 (if necessary, a conductive film 401 if the conductive film 401 is disposed between the first electronic element 400 and the core portion 101) disposed in the cavity 102. The heat dissipating portion 130 may have a plate shape extending to a region corresponding to an inner region of the cavity 102. The heat dissipating portion 130 may extend in a direction perpendicular to a first direction. As an example, the heat dissipating portion 130 may have a plate shape extending in a plane perpendicular to the first direction.

The heat dissipating portion 200 may include at least one of copper (Cu), aluminum (Al), silver (Ag), tin (Sn), gold (Au), nickel (Ni), lead (Pb), titanium (Ti), and an alloy thereof.

According to the interposer substrate and the semiconductor package according to the other embodiment described above, the heat dissipating portion with the large planar area may be formed to increase a surface area of the heat dissipation portion facing the electronic element. Thus, a heat dissipation efficiency may be improved.

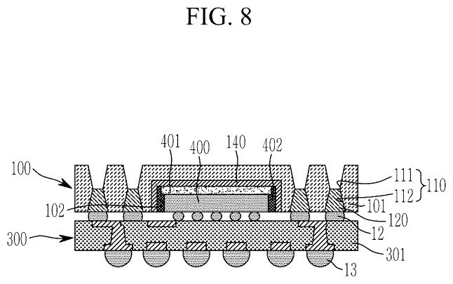

Hereinafter, an interposer substrate 100 according to another embodiment will be described with reference to FIG. 8.

FIG. 8 is a cross-sectional view showing a portion of a semiconductor package according to the other embodiment.

Referring to FIG. 8, the interposer substrate 100 according to the present embodiment is similar to the semiconductor package 10 according to the embodiment described with reference to FIG. 2 and FIG. 3. A detailed description of the same component is omitted.

Referring to FIG. 8, the interposer substrate 100 according to the present embodiment may further include a protection portion 140 covering a side surface of a cavity 102 compared with the interposer substrate 100 according to the embodiment shown in FIG. 2 and FIG. 3. The protection portion 140 may be configured to shield electromagnetic interference (EMI) by covering a side surface of the cavity 102 along a first direction and a side surface of the cavity 102 along a direction perpendicular to the first direction. The protection portion 140 may include at least one of a magnetic material and a metal material.

According to the interposer substrate and the semiconductor package according to the other embodiment described above, the interposer substrate advantageous for shielding an electromagnetic wave may be provided.

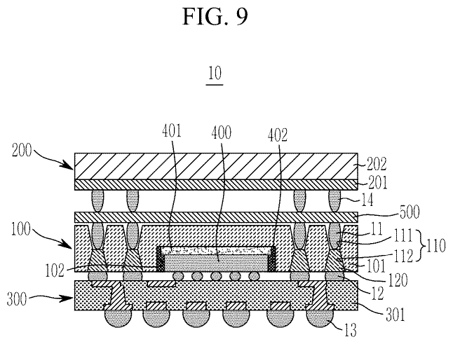

Hereinafter, a semiconductor package according to another embodiment will be described with reference to FIG. 9.

FIG. 9 is a cross-sectional view of the semiconductor package according to the other embodiment.

Referring to FIG. 9, the semiconductor package 10 according to the present embodiment is similar to the semiconductor package 10 according to the embodiment described with reference to FIG. 1. A detailed description of the same component is omitted.

Referring to FIG. 9, the semiconductor package 10 according to the present embodiment may further include a third circuit substrate (or a third circuit board) 500 disposed above an interposer substrate 100 and a fourth connection member 14 connecting the third circuit substrate 500 and an upper package 200 compared with the semiconductor package 10 according to the embodiment shown in FIG. 1.

Although not shown in FIG. 9, the third circuit substrate 500 may include an insulating layer, a conductive layer, and a via layer. The third circuit substrate 500 may function as an interposer. The upper package 200 may be connected to the third circuit substrate 500 through the fourth connection member 14. The fourth connection member 14 may be a solder ball or the like. A first connection member 11 may connect the interposer substrate 100 and the third circuit substrate 500.

According to the interposer substrate and the semiconductor package according to the other embodiment described above, an additional interposer may be easily disposed as needed without significantly changing an entire height of the semiconductor package.

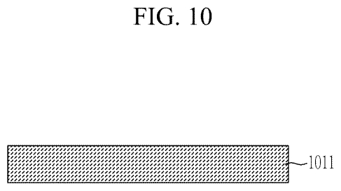

Hereinafter, a method for manufacturing the interposer substrate 100 and the semiconductor package 10 according to an embodiment will be described with reference to FIGS. 10 to 15.

FIGS. 10 to 15 are cross-sectional views showing the method for manufacturing the semiconductor package according to the embodiment.

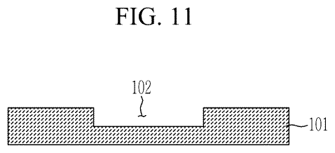

Referring to FIG. 10 and FIG. 11, the core portion 101 having the cavity 102 may be formed by etching a portion of a glass substrate 1011. The cavity 102 may be formed at the glass substrate 1011 by an etching process such as a wet etching process, a physical etching process, or the like.

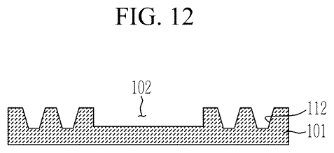

Referring to FIG. 12, the second portion 112 penetrating a portion of the core portion 101 may be formed from the second surface of the core portion 101. The second portion 112 may be formed by laser drilling.

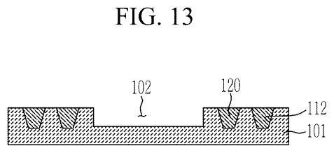

Referring to FIG. 13, the conductive member 120 may be filled inside the second portion 112. In FIG. 13, the conductive member 120 is shown to be filled in an entire second portion 112, but the present disclosure is not limited thereto, and the conductive member 120 may be filled in only a portion of the second portion 112.

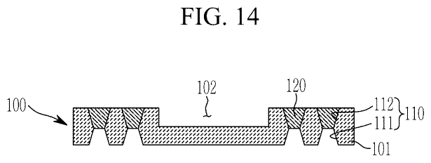

Referring to FIG. 14, the first portion 111 penetrating another portion of the core portion 101 may be formed from a first surface of the core portion 101 to be connected to the second portion 112. Thus, the via 110 including the second portion 112 and the first portion 111 may be formed. The first portion 111 may be formed by laser drilling. As an example, the first portion 111 may be formed to have a symmetrical shape with the second portion 112. The first portion 111 and the second portion 112 may be formed so that a width of each of the first portion 111 and the second portion 112 along a direction perpendicular to the first direction increases as it goes toward the outside of the core portion 101.

Referring to FIG. 14, the interposer substrate 100 of FIGS. 1 to 3 according to the above-described embodiment that includes the core portion 101, the cavity 102, and the conductive member 120 may be formed.

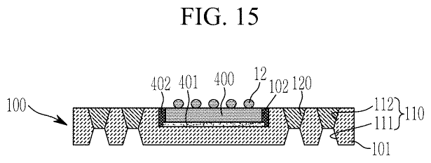

Referring to FIG. 15, the first electronic element 400 may be disposed within the cavity 102. If necessary, the conductive film 401 may be disposed between the first electronic element 400 and the core portion 101. The conductive film 401 may bond the first electronic element 400 to the core portion 101. The molding material 402 may be disposed in a space of the cavity 102 where the first electronic element 400 is not disposed. The molding material 402 may fix the first electronic element 400.

Here, referring to FIG. 1 together with FIG. 15, the first connection member 11 may be formed inside the first portion 111, and the upper package 200 may be disposed on the first connection member 11. Additionally, the second connection member 12 may be formed on the conductive member 120 filled within the second portion 112 and the first electronic element 400, and the lower package 300 may be disposed on the second connection member 12. Accordingly, the semiconductor package 10 according to the embodiment described above with reference to FIG. 1 may be formed.

According to the method for manufacturing the semiconductor package according to the above-described embodiment, occurrence of a warpage defect may be reduced because a glass core is inserted between the upper package and the lower package, thermal stability and signal count may be increased because a via is disposed at the glass core, and a power transfer characteristic may be improved. In addition, a height of the entire semiconductor package may be lowered by forming the connection member inside the via, and a via structure including the first portion and the second portion may be easily formed by forming a via connecting through holes symmetrically formed at both opposing surfaces of the glass core.

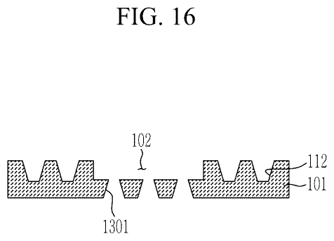

Hereinafter, a method for manufacturing the interposer substrate 100 and the semiconductor package 10 according to another embodiment will be described with reference to FIGS. 16 to 20.

FIGS. 16 to 20 are cross-sectional views showing the method for manufacturing the semiconductor package according to the other embodiment.

The core portion 101 having the cavity 102 and the second portion 112 may be formed as described above with reference to FIG. 11 and FIG. 12. Here, referring to FIG. 16, a through hole 1301 penetrating from the first surface of the core portion 101 to the cavity 102 may be formed. The through hole 1301 may be formed by laser drilling.

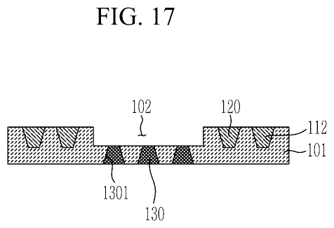

Referring to FIG. 17, the conductive member 120 may be filled inside the second portion 112. Additionally, the heat dissipating portion 130 may be formed by filling inside the through hole 1301 with a heat dissipating material.

In FIG. 17, the conductive member 120 is shown to be filled in an entire second portion 112, but the present disclosure is not limited thereto, and the conductive member 120 may be filled in only a portion of the second portion 112.

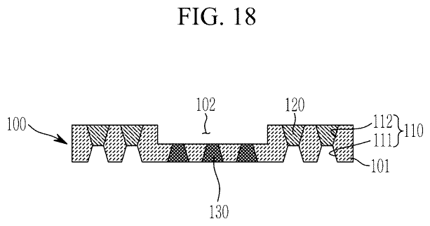

Referring to FIG. 18, the first portion 111 penetrating another portion of the core portion 101 from the first surface of the core portion 101 may be formed to form the via 110 including the second portion 112 and the first portion 111. The first portion 111 may be formed by laser drilling. As an example, the first portion 111 may be formed to have a symmetrical shape with the second portion 112. The first portion 111 and the second portion 112 may be formed so that a width of each of the first portion 111 and the second portion 112 along a direction perpendicular to the first direction increases as it goes toward the outside of the core portion 101.

Referring to FIG. 18, the interposer substrate 100 of FIG. 4 and FIG. 5 according to the other embodiment that includes the core portion 101, the cavity 102, the conductive member 120, and the heat dissipating portion 130 may be formed.

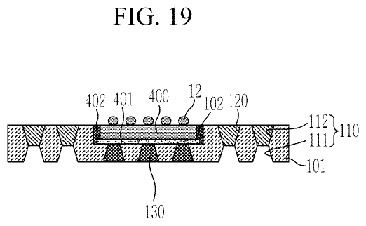

Referring to FIG. 19, the first electronic element 400 may be disposed within the cavity 102. If necessary, the conductive film 401 may be disposed between the first electronic element 400 and the core portion 101. The conductive film 401 may bond the first electronic element 400 to the core portion 101. The molding material 402 may be disposed in a space of the cavity 102 where the first electronic element 400 is not disposed. The molding material 402 may fix the first electronic element 400.

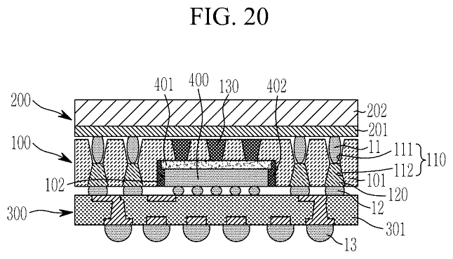

Referring to FIG. 20, the first connection member 11 may be formed inside the first portion 111, and the upper package 200 may be disposed on the first connection member 11. Additionally, the second connection member 12 may be formed on the conductive member 120 filled within the second portion 112 and the first electronic element 400, and the lower package 300 may be disposed on the second connection member 12. Accordingly, the semiconductor package 10 according to the other embodiment may be formed.

According to the method for manufacturing the semiconductor package according to the other embodiment, occurrence of a warpage defect may be reduced because a glass core is inserted between the upper package and the lower package, thermal stability and signal count may be increased because a via is disposed at the glass core, and a power transfer characteristic may be improved. In addition, a height of the entire semiconductor package may be lowered by forming the connection member inside the via, and a via structure including the first portion and the second portion may be easily formed and a heat generated from the electronic element disposed in the cavity may be efficiently transferred and dispersed to the outside of the interposer substrate through the heat dissipating portion by forming a via connecting through holes symmetrically formed at both opposing surfaces of the glass core.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An interposer substrate comprising:
a core portion that includes a first surface and a second surface opposing each other, includes a via penetrating from the first surface to the second surface, and includes glass; and
a conductive member that is disposed in only a portion of the via,
wherein the via comprises:
a first portion penetrating a portion of the core portion from the first surface; and
a second portion penetrating another portion of the core portion to be connected to the first portion from the second surface and at which the conductive member is disposed.

2. The interposer substrate of claim 1, wherein the core portion includes a cavity on the second surface, and the via is provided in a plural number around the cavity.

3. The interposer substrate of claim 2, wherein the plurality of vias are disposed along a circumference of the cavity.

4. The interposer substrate of claim 2, further comprising a heat dissipating portion penetrating and extending from the first surface to the cavity.

5. The interposer substrate of claim 4, wherein the heat dissipating portion is provided in a plural number, and the plurality of heat dissipating portions are disposed to be spaced apart from each other.

6. The interposer substrate of claim 4, wherein the first surface and the second surface oppose each other in a first direction, and the heat dissipating portion has a plate shape extending in a direction perpendicular to the first direction.

7. The interposer substrate of claim 2, further comprising a protection portion shielding electromagnetic interference by covering a side surface of the cavity.

8. The interposer substrate of claim 1, wherein in the first portion or the second portion, a width of one outer end of the core portion is greater than a width of the other inner end of the core portion.

9. The interposer substrate of claim 1, wherein the first portion and the second portion have a symmetrical shape.

10. The interposer substrate of claim 1, wherein among the first portion and the second portion, the conductive member is disposed only in the second portion.

11. An interposer substrate comprising:
a core portion that includes a first surface and a second surface opposing each other, includes a via penetrating from the first surface to the second surface, includes a cavity on the second surface, and includes glass;
a conductive member that is disposed in a portion of the via; and
a heat dissipating portion that penetrates and extends from the first surface to the cavity,
wherein the via comprises:
a first portion penetrating a portion of the core portion from the first surface; and
a second portion penetrating another portion of the core portion to be connected to the first portion from the second surface and at which the conductive member is disposed.

12. The interposer substrate of claim 11, wherein the via is provided in a plural number around the cavity.

13. The interposer substrate of claim 12, wherein the plurality of vias are disposed along a circumference of the cavity.

14. The interposer substrate of claim 11, wherein the heat dissipating portion is provided in a plural number, and the plurality of heat dissipating portions are disposed to be spaced apart from each other.

15. The interposer substrate of claim 11, wherein the first surface and the second surface oppose each other in a first direction, and the heat dissipating portion extends in a direction perpendicular to the first direction.

16. The interposer substrate of claim 11, wherein in the first portion or the second portion, a width of one outer end of the core portion is greater than a width of the other inner end of the core portion.

17. The interposer substrate of claim 11, wherein the first portion and the second portion have a symmetrical shape.

18. A semiconductor package comprising:
an interposer substrate;
an upper package that is disposed at one side of the interposer substrate and includes a first circuit substrate including an insulating layer and a circuit layer; and
a connection member that is disposed above one surface of the interposer substrate to connect the upper package and the interposer substrate,
wherein the interposer substrate includes:
a core portion that includes a first surface and a second surface opposing each other, includes a via penetrating from the first surface to the second surface, and includes glass, and
a conductive member that is filled in a portion of the via, and
the via includes a first portion penetrating a portion of the core portion from the first surface and providing a space in which the connection member is disposed and a second portion penetrating another portion of the core portion to be connected to the first portion from the second surface and at which the conductive member is disposed.

19. The semiconductor package of claim 18, further comprising a lower package disposed on the other side of the interposer substrate and including a second circuit substrate including an insulating layer and a circuit layer.

20. The semiconductor package of claim 18, wherein the core portion has a cavity on the second surface, and further comprising a heat dissipating portion penetrating and extending from the first surface to the cavity.
